(19) United States
(12) Patent Application Publication
(10) Pub. No.: US 2014/0254106 A1
(43) Pub. Date: Sep. 11, 2014

(54) Ejector Lever Locking Mechanism Design For Conduction Cooled Circuit Board Assembly

(71) Applicant: Emerson Network Power-Embedded Computing, Inc., (US)

(72) Inventor: Carmelo Engracia BAQUIANO, Dela Paz Pasig (PH)

(73) Assignee: EMERSON NETWORK POWER - EMBEDDED COMPUTING, INC., Tempe, AZ (US)

(21) Appl. No.: 13/793,040

(22) Filed: Mar. 11, 2013

(51) Int. Cl. H05K 5/02

(52) U.S. Cl. CPC H05K 5/0221
USPC 361/726

(57) ABSTRACT

An ejector lever locking mechanism rotatably connected to a heat frame and releasably engaged to a module body includes a lever body rotatably connected to the heat frame. The lever body includes a recessed wall created in a lever body elongated slot. The elongated slot extends only partially through a body thickness of the lever body. The recessed wall is positioned proximate to a lever body aperture defining a through aperture extending through the lever body including the elongated slot. A lock pin has a first portion fixed to a module body and a second portion extending through the lever body aperture. The second portion has an engagement member overlapping the recessed wall defining a lever body engaged position acting to releasably connect the heat frame and circuit board assembly to an electronics cabinet.

### FIELD

The present disclosure relates to conduction cooled circuit board assemblies.

### BACKGROUND

This section provides background information related to the present disclosure which is not necessarily prior art.

Conduction cooled circuit board assemblies have a heat frame that encompasses components positioned within the assembly. Ejector mechanisms are provided to open and access the enclosed components. Common ejector mechanism designs are subject to noise, specifically noise that is generated due to mechanism rattling induced as the circuit board assembly is subjected to vibration in its operating environment. As the vibration increases over time due to wear, the ejector mechanism may loosen and/or fail.

### SUMMARY

This section provides a general summary of the disclosure, and is not a comprehensive disclosure of its full scope or all of its features.

According to several aspects, an ejector lever locking mechanism is rotatably connected to a heat frame of a circuit board assembly. The ejector lever locking mechanism includes a lever body rotatably connected to the heat frame using a connecting pin rotatably received in the lever body. The lever body includes a recessed wall created in a lever body elongated slot. The elongated slot extends only partially through a body thickness of the lever body. The recessed wall is positioned proximate to a lever body aperture defining a through aperture extending through the lever body including the elongated slot. A lock pin is fixed to a module body and extends through the lever body aperture in a lever body engaged position. The lock pin has an engagement member overlapping the recessed wall defining the lever body engaged position, releasably connecting the circuit board assembly to an electronics cabinet.

According to other aspects, an ejector lever locking mechanism is rotatably connected to a heat frame of a circuit board assembly and releasably engaged to a module body. The lever body includes a recessed wall created in a lever body elongated slot. The elongated slot extends only partially through a body thickness of the lever body. The recessed wall is positioned proximate to a lever body aperture defining a through aperture extending through the lever body including the elongated slot. A lock pin has a first portion fixed to a module body and a second portion extending through the lever body aperture. The second portion has an engagement member overlapping the recessed wall defining a lever body engaged position acting to releasably connect the heat frame and the circuit board assembly to an electronics cabinet.

According to further aspects, an ejector lever locking mechanism system includes a heat frame and a module body releasably connected to the heat frame by a lever body. The lever body is rotatably connected to the heat frame using a connecting pin rotatably received in the lever body. The lever body includes a recessed wall created in a lever body elongated slot. The elongated slot extends only partially through a body thickness of the lever body. The recessed wall is positioned proximate to a lever body aperture defining a through aperture extending through the lever body including the elongated slot. A lock pin has a first portion fixed to the module body and a second portion extending through a heat frame aperture created in the module body. The second portion of the lock pin further extends through the lever body aperture and has an engagement member overlapping the recessed wall defining a lever body engaged position releasably connecting the heat frame to the module body.

Further areas of applicability will become apparent from the description provided herein. The description and specific examples in this summary are intended for purposes of illustration only and are not intended to limit the scope of the present disclosure.

### DRAWINGS

The drawings described herein are for illustrative purposes only of selected embodiments and not all possible implementations, and are not intended to limit the scope of the present disclosure.

FIG. 1 is a top right perspective view of a locking mechanism design of the present disclosure in a released position;

FIG. 2 is a top plan view of the locking mechanism of FIG. 1 in a closed position;

FIG. 3 is a front elevational cross sectional view taken at section 3 of FIG. 2;

FIG. 4 is a front elevational cross sectional view taken at area 4 of FIG. 2;

FIG. 5 is a front elevational view of an alternate embodiment of a lock pin;

FIG. 6 is a front elevational view of a second alternate embodiment of a lock pin;

FIG. 7 is a front elevational view of a third alternate embodiment of a lock pin;

FIG. 8 is a top left perspective view of an electronics cabinet slidably receiving multiple circuit board assemblies; and

FIG. 9 is cross sectional end elevational view taken at section 9 of FIG. 8.

Corresponding reference numerals indicate corresponding parts throughout the several views of the drawings.

### DETAILED DESCRIPTION

Example embodiments will now be described more fully with reference to the accompanying drawings.

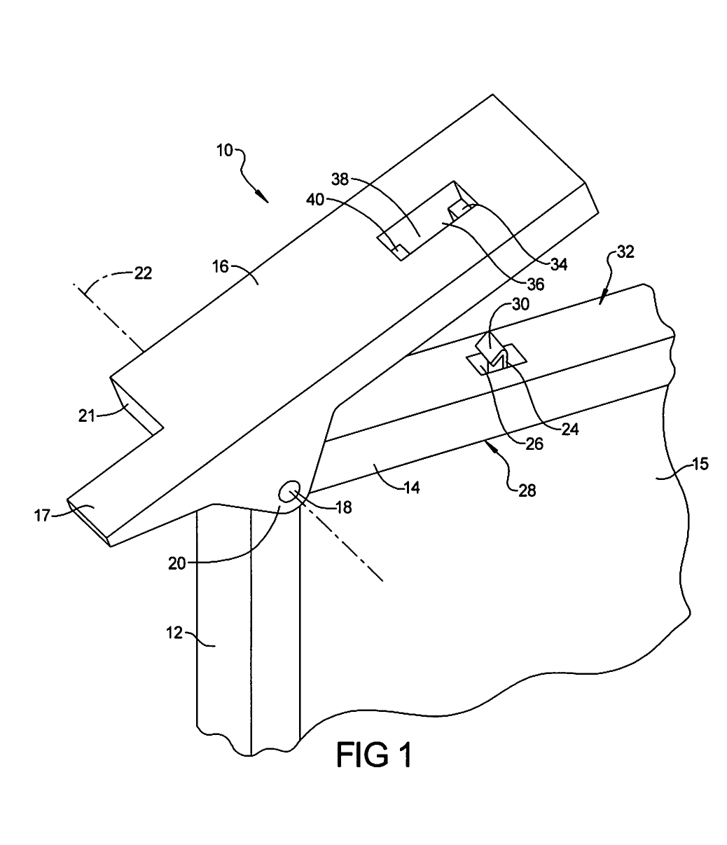

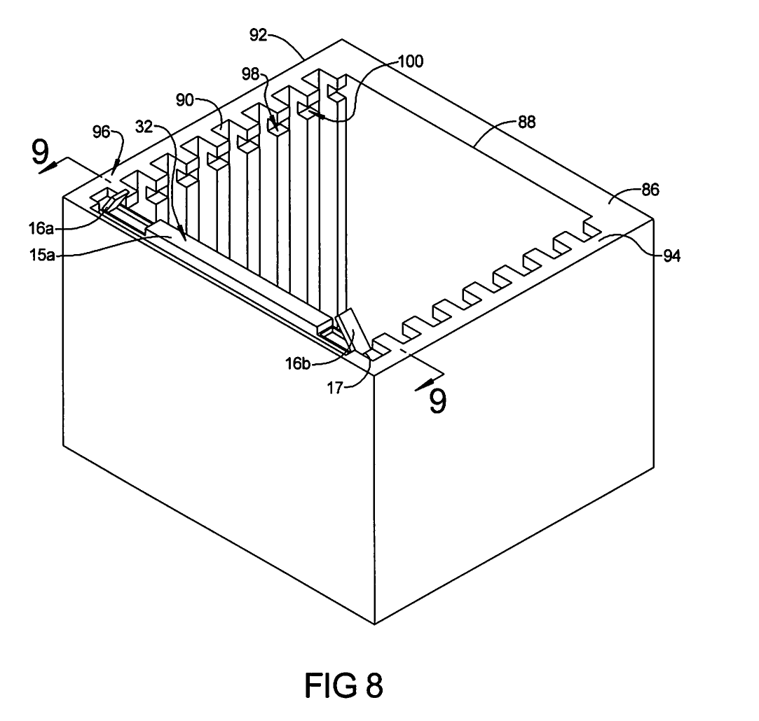

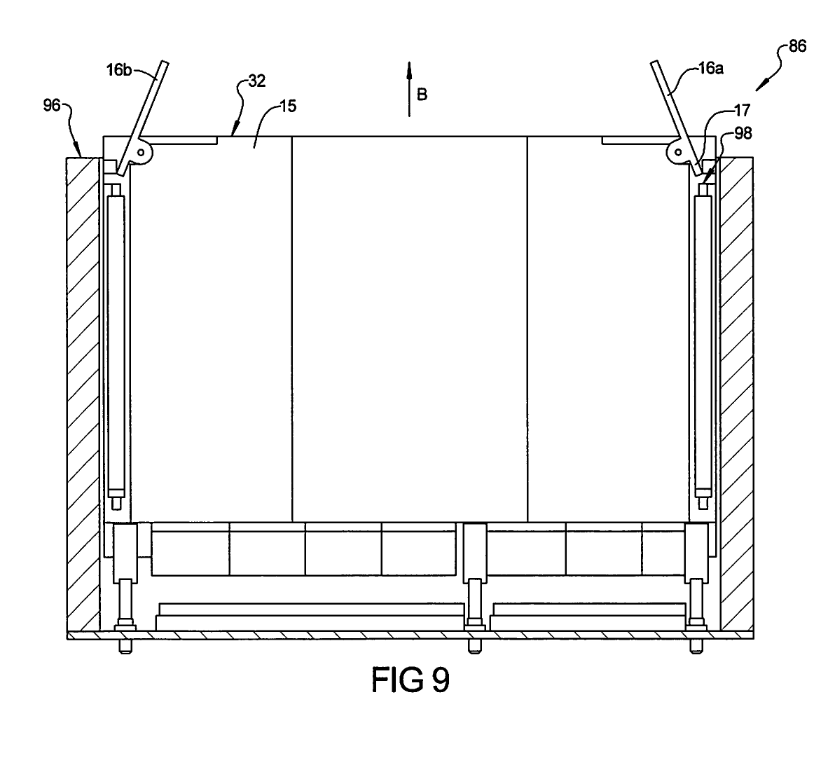

Referring to FIG. 1, an ejector lever locking mechanism 10 is rotatably connected to a heat frame 12 and releasably engages a module body 14. Each heat frame 12 and module body 14 partially enclose one of multiple conduction cooled circuit board assemblies 15. Ejector lever locking mechanism 10 includes a lever body 16 made for example of a metal such as aluminum. Lever body 16 includes a freely extending lever arm 17 which is used to release the heat frame 12, module body 14 and circuit board assemblies 15 from an electronics cabinet shown and described in reference to FIGS. 8 and 9. Lever body 16 is rotatably connected to heat frame 12 using a connecting pin 18 received through opposed first and second wings 20, 21 (only first wing 20 is clearly visible in this view) connected to and according to several aspects integrally extending from lever body 16. Connecting pin 18 defines an axis of rotation 22 for lever body 16.

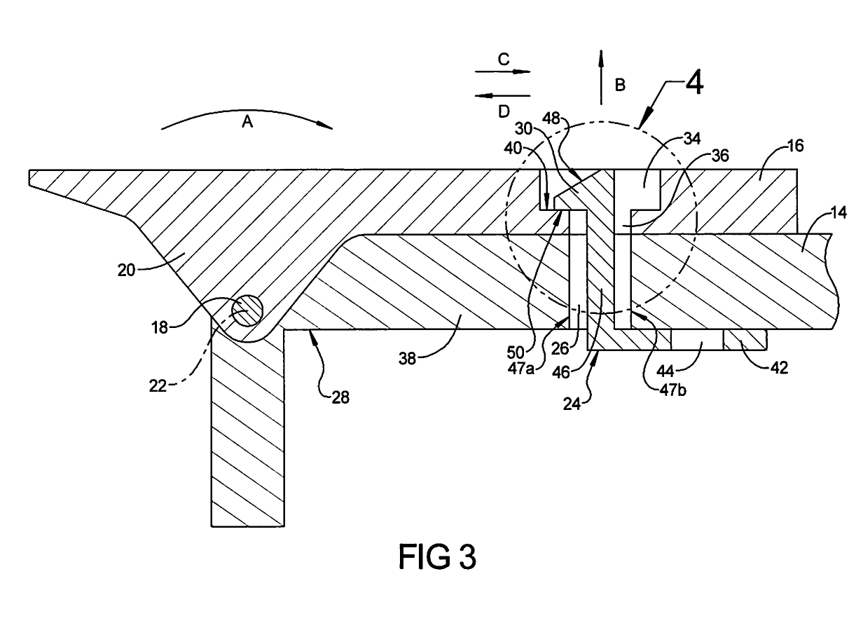

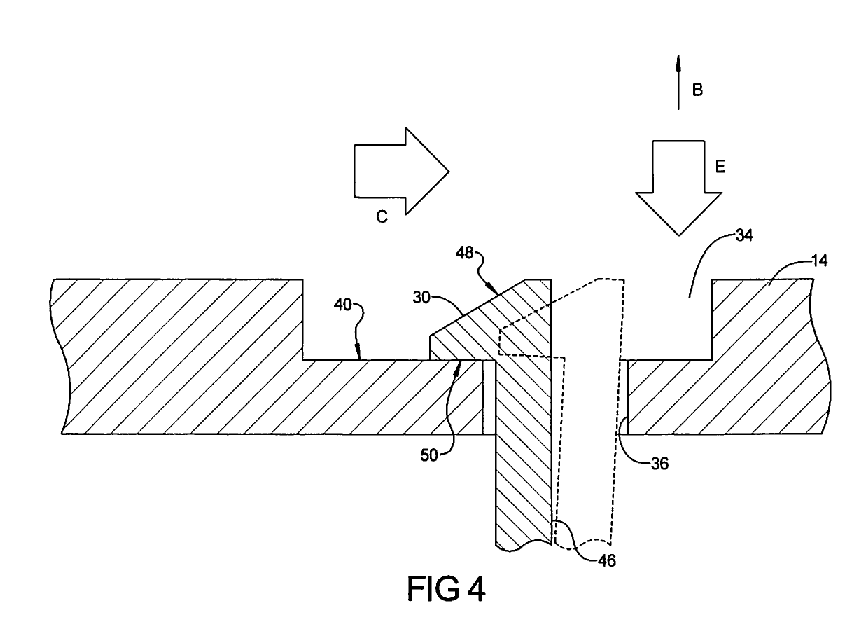

In an ejector lever locking mechanism 10 open or released position shown, the lever body 16 is rotated freely with respect to and therefore disengaged from a lock pin 24 which is fixed to the module body 14, thereby allowing the heat frame 12, module body 14 and circuit board assemblies 15 to be released from the cabinet. A first portion of lock pin 24 extends through a heat frame aperture 26 and a second portion is connected to a first side 28 of module body 14. A hook-shaped engagement member 30 of the first portion extends freely above a second side 32 of module body 14. By the fixed connection of lock pin 24 with first side 28 of module body 14, the engagement member 30 can flex or deflect within heat frame aperture 26 when engagement member 30 is contacted by lever body 16, as will be described in greater detail with respect to FIGS. 3 and 4.

Lever body 16 includes a lever body elongated slot 34 created partially through a body thickness of lever body 16. A lever body aperture 36 is a through aperture extending through lever body 16 including elongated slot 34. When moved away from the released position of lever body 16 to an engaged position of lever body 16 with module body 14 (shown in reference to FIG. 3), lever body aperture 36 is aligned with and receives engagement member 30 by sliding contact and deflection between engagement member 30 with a contact edge 38 defined by lever body aperture 36. After deflection of engagement member 30 by contact with contact edge 38, the engagement member 30 rebounds to releasably engage a recessed wall 40 provided within elongated slot during creation of elongated slot 34.

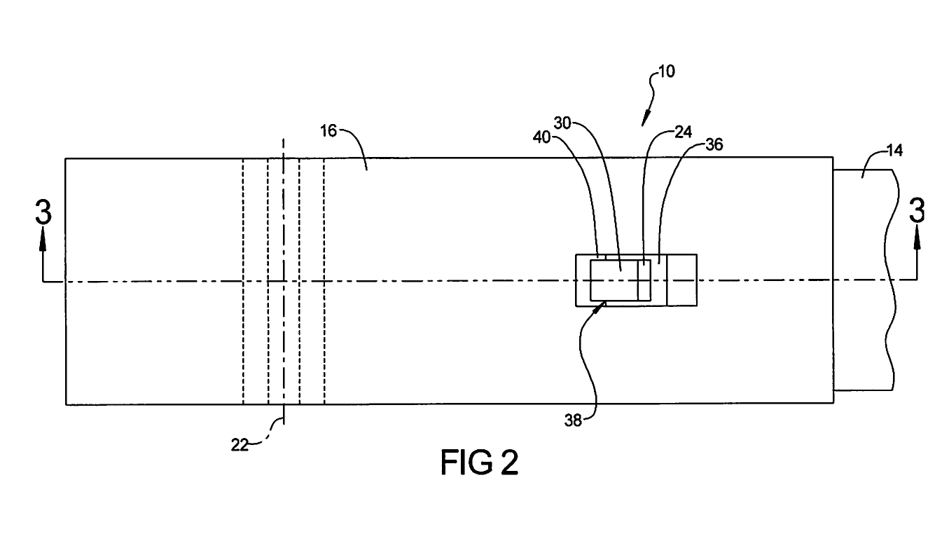

Referring to FIG. 2 and again to FIG. 1, in the engaged position of lever body 16 of ejector lever locking mechanism 10 the lock pin 24 is in direct contact with contact edge 38 such that engagement member 30 overhangs recessed wall 40, which acts to prevent release of lever body 16. A force must be subsequently applied to lock pin 24 to displace engagement member 30 of lock pin 24 into alignment with lever body aperture 36 to thereby allow release of lever body 16 and subsequent rotation with respect to axis of rotation 22.

Referring to FIG. 3 and again to FIGS. 1-2, lever body 16 is shown in the engaged position after rotation in a direction of rotation “A” about axis of rotation 22 and is releasably retained in the engaged position by engagement member 30. According to several aspects lock pin 24 is created by bending an initially flat plate or strip of a metal such as spring steel. Lock pin 24 includes a first portion 42 which is substantially flat/planar which is abutted against the first side 28 of module body 14 as previously noted. First portion 42 can be welded such as by fillet or spot welding to first side 28, and/or can also include a bore 44 which receives a fastener (not shown) to fastenably couple first portion 42 to module body 14. A second portion 46 of lock pin 24 defines a column oriented normal to first portion 42 which extends freely through heat frame aperture 26. It is further noted heat frame aperture 26 is initially sized to allow free passage of engagement member 30 when second portion 46 is positioned in heat frame aperture 26, such that second portion 46 is freely spaced from opposed walls 47a, 47b defined by heat frame aperture 26. This clearance allows second portion 46 to freely deflect in opposite directions from the nominal position shown within heat frame aperture 26.

As lever body 16 is rotated toward the engaged position the engagement member 30 is slidably displaced in a receiving direction “B” until an angular or tapered face 48 of engagement member 30 strikes contact edge 38 causing engagement member 30 together with second portion 46 of lock pin 24 to deflect in a displacement direction “C”. This deflection causes bending in second portion 46. Free space is provided in each of lever body aperture 36 and heat frame aperture 26 for this deflection to occur. A contact face 50 of engagement member 30 is normally oriented parallel to recessed wall 40. When contact face 50 extends freely above recessed wall 40, a spring force created during deflection of second portion 46 causes second portion 46 together with engagement member 30 to displace in an opposite engagement direction “D” allowing contact face 50 to move past contact edge 38. This overlap of contact face 50 with respect to recessed wall 40 restricts release of lever body 16.

Referring to FIG. 4 and again to FIGS. 1-3, to release lever body 16 from the engaged position the operator positions a finger in elongated slot 34 and directly contacts tapered face 48. By pressing in the displacement direction “C” the second portion 46 is moved within lever body aperture 36 until contact face 50 is displaced freely away from recessed wall 40. By then pushing engagement member 30 in a release direction “E” which is opposite to the receiving direction “B” the engagement member 30 is displaced through lever body aperture 36 allowing lever body 16 to be rotated to the open or released position shown in FIG. 1.

Referring generally to FIGS. 5-7 and again to FIG. 3, the lock pin 24 can be replaced by several alternate designs of a lock pin. Referring specifically to FIG. 5, in a first alternate aspect, a lock pin 52 is formed entirely by bending and therefore provides a substantially common body thickness “T₁” throughout. A first portion 54 is oppositely directed with respect to first portion 42 of lock pin 24. A second portion 56 is oriented normal to first portion 54. A third portion 58 is angularly oriented with respect to second portion 56, for example at a 45 degree angle with respect to second portion 56. Third portion 58 therefore provides a tapered face 48′ similarly oriented with respect to tapered face 48. A fourth portion 60 integrally connected to an end of third portion 58 extends toward second portion 56. Fourth portion 60 provides a contact face 50′ similar in orientation and function to contact face 50.

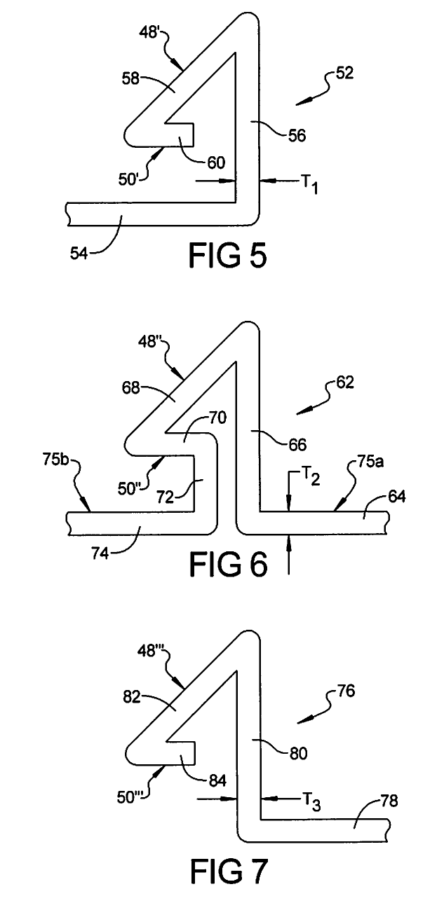

Referring to FIG. 6 and again to FIG. 3, in a second alternate aspect, a lock pin 62 is formed entirely by bending and therefore provides a substantially common body thickness “T₂” throughout. According to several aspects, body thickness “T₂” is equal to but can also be different from body thickness “T₁”. A first portion 64 is similarly directed with respect to first portion 42 of lock pin 24. A second portion 66 is oriented normal to first portion 64. A third portion 68 is angularly oriented with respect to second portion 66, for example at a 45 degree angle with respect to second portion 66. Third portion 68 therefore provides a tapered face 48″ similarly oriented with respect to tapered face 48. A fourth portion 70 integrally connected to an end of third portion 68 extends toward second portion 66. Fourth portion 70 provides a contact face 50″ similar in orientation and function to contact face 50. A fifth portion 72 integrally connected to an end of fourth portion 70 is oriented parallel to second portion 66. A sixth portion 74 integrally connected to an end of fifth portion 72 is oriented co-planar with respect to first portion 64. Parallel and co-planar faces 75a, 75b of first and sixth portions 64, 74 will both be placed in direct contact with first side 28 of module body 14 on opposite sides of heat frame aperture 26.

Referring to FIG. 7 and again to FIG. 3, in a third alternate aspect, a lock pin 76 is formed entirely by bending and therefore provides a substantially common body thickness “T₃” throughout. According to several aspects, body thickness “T₃” is equal to but can also be different from body thickness “T₁”. A first portion 78 is similarly directed with respect to first portion 42 of lock pin 24. A second portion 80 is oriented normal to first portion 78. A third portion 82 is angularly oriented with respect to second portion 80, for example at a 45 degree angle with respect to second portion 80. Third portion 82 therefore provides a tapered face 48′″ similarly oriented with respect to tapered face 48. A fourth portion 84 integrally connected to an end of third portion 82 extends toward second portion 80. Fourth portion 84 provides a contact face 50′″ similar in orientation and function to contact face 50.

Referring to FIG. 8 and again to FIGS. 1-4, an electronics cabinet 86 includes a component cavity inner wall 88 defining an inner cavity. Multiple component slots 90 are created in opposed first and second side walls 92, 94. Each of the component slots slidably receives one of the circuit board assemblies 15. An exemplary circuit board assembly 15a is shown in an end component slot having its lever bodies 16a, 16b in the rotated/released position, which causes a portion of the circuit board assembly 15a to be raised above a cabinet wall surface 96 for subsequent ease in removing the circuit board assembly 15a. Each of the component slots 90 provides a cam surface 98 which is positioned below and spatially separated from a restraining member 100. When the circuit board assemblies 15 are in their installed positions, the lever bodies 16a, 16b are positioned parallel to the second side 32 of module body 14. The lever arm 17 of each of the lever bodies 16a, 16b is positioned above the cam surface 98 and in direct contact with an underside of the restraining member 100 on each end of the component slots 90. The lever arms 17 in this position prevent release of the circuit board assemblies 15.

Referring to FIG. 9, as lever bodies 16a, 16b are rotated to the release position, each lever arm 17 presses downwardly against the proximate cam surface 98 which levers the circuit board assemblies 15 in an upward circuit board release direction “F”. The circuit board assemblies 15 can be removed/repaired and/or replaced when in the release position. Reversing the removal steps and rotating the lever bodies 16a, 16b back to the engaged position shown in FIG. 3 locks the circuit board assemblies 15 in place.

According to several aspects, the ejector lever locking mechanism 10 is rotatably connected to the heat frame 12 and is releasably engaged to the module body 14. Ejector lever locking mechanism 10 includes the lever body 16 which is rotatably connected to the heat frame 12. The lever body 16 includes the recessed wall 40 created in the lever body elongated slot 34. The elongated slot 34 extends only partially through a body thickness of the lever body 16. The recessed wall 40 is positioned proximate to the lever body aperture 36 which defines a through aperture 36 extending through the lever body 16 including the elongated slot 34. A lock pin 24 has its first portion 42 fixed to the module body 14 and its second portion 46 extending through the lever body aperture 36. The second portion 46 has an engagement member 30 overlapping the recessed wall 40 thereby defining the lever body engaged position which acts to releasably connect the heat frame 12 to the module body 14.

Example embodiments are provided so that this disclosure will be thorough, and will fully convey the scope to those who are skilled in the art. Numerous specific details are set forth such as examples of specific components, devices, and methods, to provide a thorough understanding of embodiments of the present disclosure. It will be apparent to those skilled in the art that specific details need not be employed, that example embodiments may be embodied in many different forms and that neither should be construed to limit the scope of the disclosure. In some example embodiments, well-known processes, well-known device structures, and well-known technologies are not described in detail.

The terminology used herein is for the purpose of describing particular example embodiments only and is not intended to be limiting. As used herein, the singular forms “a,” “an,” and “the” may be intended to include the plural forms as well, unless the context clearly indicates otherwise. The terms “comprises,” “comprising,” “including,” and “having,” are inclusive and therefore specify the presence of stated features, integers, steps, operations, elements, and/or components, but do not preclude the presence or addition of one or more other features, integers, steps, operations, elements, components, and/or groups thereof. The method steps, processes, and operations described herein are not to be construed as necessarily requiring their performance in the particular order discussed or illustrated, unless specifically identified as an order of performance. It is also to be understood that additional or alternative steps may be employed.

When an element or layer is referred to as being “on,” “engaged to,” “connected to,” or “coupled to” another element or layer, it may be directly on, engaged, connected or coupled to the other element or layer, or intervening elements or layers may be present. In contrast, when an element is referred to as being “directly on,” “directly engaged to,” “directly connected to,” or “directly coupled to” another element or layer, there may be no intervening elements or layers present. Other words used to describe the relationship between elements should be interpreted in a like fashion (e.g., “between” versus “directly between,” “adjacent” versus “directly adjacent,” etc.). As used herein, the term “and/or” includes any and all combinations of one or more of the associated listed items.

Although the terms first, second, third, etc. may be used herein to describe various elements, components, regions, layers and/or sections, these elements, components, regions, layers and/or sections should not be limited by these terms. These terms may be only used to distinguish one element, component, region, layer or section from another region, layer or section. Terms such as “first,” “second,” and other numerical terms when used herein do not imply a sequence or order unless clearly indicated by the context. Thus, a first element, component, region, layer or section discussed below could be termed a second element, component, region, layer or section without departing from the teachings of the example embodiments.

Spatially relative terms, such as “inner,” “outer,” “beneath,” “below,” “lower,” “above,” “upper,” and the like, may be used herein for ease of description to describe one element or feature's relationship to another element(s) or feature(s) as illustrated in the figures. Spatially relative terms may be intended to encompass different orientations of the device in use or operation in addition to the orientation depicted in the figures. For example, if the device in the figures is turned over, elements described as “below” or “beneath” other elements or features would then be oriented “above” the other elements or features. Thus, the example term “below” can encompass both an orientation of above and below. The device may be otherwise oriented (rotated 90 degrees or at other orientations) and the spatially relative descriptors used herein interpreted accordingly.

The foregoing description of the embodiments has been provided for purposes of illustration and description. It is not intended to be exhaustive or to limit the disclosure. Individual elements or features of a particular embodiment are generally not limited to that particular embodiment, but, where applicable, are interchangeable and can be used in a selected embodiment, even if not specifically shown or described. The same may also be varied in many ways. Such variations are not to be regarded as a departure from the disclosure, and all such modifications are intended to be included within the scope of the disclosure.

What is claimed is:

1. An ejector lever locking mechanism rotatably connected to a heat frame of a circuit board assembly, comprising:
a lever body rotatably connected to the heat frame using a connecting pin rotatably received in the lever body, the lever body including a recessed wall created in a lever body elongated slot, the elongated slot extending only partially through a body thickness of the lever body, the recessed wall positioned proximate to a lever body aperture defining a through aperture extending through the lever body including the elongated slot; and
a lock pin fixed to a module body and extending through the lever body aperture in a lever body engaged position, the lock pin having an engagement member overlapping the recessed wall defining the lever body engaged position, releasably connecting the circuit board assembly to an electronics cabinet.

2. The ejector lever locking mechanism of claim 1, wherein the lock pin includes a first portion connected to a first side of the module body and a second portion extending through a heat frame aperture having the engagement member integrally connected to the second portion.

3. The ejector lever locking mechanism of claim 2, wherein the engagement member defines a hook-shaped portion and extends freely above a second side of the module body oppositely facing with respect to the first side, the engagement member having a contact face oriented parallel to the recessed wall.

4. The ejector lever locking mechanism of claim 1, wherein the heat frame aperture is sized to allow deflection of the second portion of the lock pin within the heat frame aperture as the second portion including the engagement member are received in the lever body aperture.

5. The ejector lever locking mechanism of claim 1, wherein the engagement member includes a tapered face.

6. The ejector lever locking mechanism of claim 5, wherein during rotation to reach the engaged position of the lever body with the module body the lever body aperture is aligned with and receives the engagement member in the lever body aperture, and the tapered face of the engagement member directly contacts a contact edge defined where the lever body aperture meets the recessed wall causing deflection of the lock pin until the engagement member extends past the contact edge in the elongated slot.

7. The ejector lever locking mechanism of claim 1, wherein the lever body aperture is sized to slidably receive the engagement member, and to release the ejector lever locking mechanism from the engaged position the engagement member is manually displaced deflecting the lock pin until the engagement member is freely aligned with the lever body aperture, positioning the engagement member to be slidably displaced out the lever body aperture.

8. The ejector lever locking mechanism of claim 1, wherein in the engaged position of the lever body the lock pin is in direct contact with a contact edge defined where the lever body aperture meets the recessed wall, the engagement member having a contact face oriented parallel to and in direct contact with the recessed wall thereafter acting to resist release of the lever body.

9. The ejector lever locking mechanism of claim 1, wherein:
the heat frame and module body partially enclose a conduction cooled circuit board; and
the connecting pin defines an axis of rotation of the lever body.

10. The ejector lever locking mechanism of claim 1, wherein the lever body includes a freely extending lever arm oppositely positioned about the connecting pin with respect to the recessed wall, the lever arm when the lever body is rotated about the connecting pin contacting a cam surface of an electronics cabinet acting to lever the circuit board assembly partially out of the electronics cabinet.

11. The ejector lever locking mechanism of claim 1, wherein the lever body further includes opposed first and second wings having the connecting pin extending through the first and second wings.

12. An ejector lever locking mechanism rotatably connected to a heat frame of a circuit board assembly and releasably engaged to a module body, comprising:
a lever body rotatably connected to the heat frame, the lever body including a recessed wall created in a lever body elongated slot, the elongated slot extending only partially through a body thickness of the lever body, the recessed wall positioned proximate to a lever body aperture defining a through aperture extending through the lever body including the elongated slot; and
a lock pin having a first portion fixed to a module body and a second portion extending through the lever body aperture, the second portion having an engagement member overlapping the recessed wall defining a lever body engaged position acting to releasably connect the heat frame and circuit board assembly to an electronics cabinet.

13. The ejector lever locking mechanism of claim 12, wherein the lock pin includes a first portion connected to a first side of the module body and a second portion, the second portion extending through a heat frame aperture.

14. The ejector lever locking mechanism of claim 13, wherein the second portion of the lock pin has the engagement member integrally connected thereto, the engagement member further including a tapered face angularly oriented with respect to the second portion.

15. The ejector lever locking mechanism of claim 12, wherein the engagement member further includes a contact face oriented parallel to the first portion, the contact face in direct contact with the recessed wall in the lever body engaged position.

16. The ejector lever locking mechanism of claim 12, wherein the second portion of the lock pin is freely positioned in both the lever body aperture and the heat frame aperture in the lever body engaged position such that the second portion when deflected in both the lever body aperture and the heat frame aperture permits the engagement member to move freely away from the recessed wall.

17. The ejector lever locking mechanism of claim 12, further including a connecting pin rotatably connecting the lever body to the heat frame;
wherein the lever body includes a freely extending lever arm oppositely positioned about the connecting pin with respect to the recessed wall, the lever arm when the lever body is rotated about the connecting pin contacting a cam surface of the electronics cabinet acting to lever the circuit board assembly partially out of the electronics cabinet.

18. An ejector lever locking mechanism system, comprising:
a heat frame;
a module body releasably connected to the heat frame;
a lever body rotatably connected to the heat frame using a connecting pin rotatably received in the lever body, the lever body including:
a recessed wall created in a lever body elongated slot, the elongated slot extending only partially through a body thickness of the lever body, the recessed wall positioned proximate to a lever body aperture defining a through aperture extending through the lever body including the elongated slot; and
a lock pin having a first portion fixed to the module body and a second portion extending through a heat frame aperture created in the module body, the second portion of the lock pin further extending through the lever body aperture and having an engagement member overlapping the recessed wall defining a lever body engaged position releasably connecting the heat frame to the module body.

19. The ejector lever locking mechanism system of claim 18, wherein the lock pin includes:
a third portion having a tapered face directly contacting a contact edge defined where the lever body aperture meets the recessed wall; and
a fourth portion oriented parallel to the first portion and having a contact face contacting the recessed wall in the engaged position.

20. The ejector lever locking mechanism system of claim 18, wherein the lock pin includes:
a third portion having a tapered face angularly oriented with respect to the first portion;
a fourth portion oriented parallel to the first portion and having a contact face contacting the recessed wall in the engaged position; and
a fifth portion oriented parallel to the second portion.

21. The ejector lever locking mechanism system of claim 18, wherein the lock pin includes a constant body thickness throughout both the first and second portions.

22. The ejector lever locking mechanism system of claim 18, wherein the lock pin includes a third portion oriented co-planar to the first portion, both the first and third portions being fixed to the module body oppositely about the heat frame aperture.
